(19) United States
(12) Patent Application Publication
(10) Pub. No.: US 2007/0252261 A1
(43) Pub. Date: Nov. 1, 2007

(54) SEMICONDUCTOR DEVICE PACKAGE

(76) Inventors: Meng-Jen Wang, Ping-Tung Hsien (TW); Kuo-Pin Yang, Kao-Hsiung Hsien (TW); Sheng-Yang Peng, Kao-Hsiung City (TW); Wei-Min Hsiao, Kao-Hsiung City (TW)

Correspondence Address: NORTH AMERICA INTELLECTUAL PROPERTY CORPORATION, P.O. BOX 506, MERRIFIELD, VA, 22116, US

(21) Appl. No.: 11/612,457

(22) Filed: Dec. 18, 2006

(30) Foreign Application Priority Data
Apr. 28, 2006 (TW) 095115344

(51) Int. Cl. H01L 23/02

(52) U.S. Cl. 257/686

(57) ABSTRACT

The present invention relates to a semiconductor device package, comprising a carrier, a first semiconductor device, a second semiconductor device, a plurality of conductive elements, a pre-mold and a lid. The first semiconductor device is electrically connected to the carrier. The second semiconductor device is disposed above the first semiconductor device. The conductive elements are used for electrically connecting the second semiconductor device and the carrier. The pre-mold and the carrier form an accommodating space for accommodating the first semiconductor device, the second semiconductor device and the conductive elements. The lid is adhered to the pre-mold for covering the opening of the pre-mold. As a result, the pre-mold is formed by molding, the manufacture process of the present invention is simpler than that of the conventional semiconductor device package.

### BACKGROUND OF THE INVENTION

1. Field of the Invention

The invention relates to a semiconductor device package, and more particularly, to a semiconductor device package having a pre-mold therein.

2. Description of the Prior Art

Please refer to FIG. 1, which shows a sectional-view schematic diagram of a conventional semiconductor device package disclosed by U.S. Pat. No. 6,781,231 B2. The conventional semiconductor device package 1 contains a substrate 11, a plurality of surface mountable components 12, and a lid 13.

The substrate 11 has an upper surface 111 and a lower surface 112. The surface mountable components 12 are micro-electro-mechanical system (MEMS) devices, such as transducers, microphones, integrated circuits (ICs), or the like. The surface mountable components 12 are horizontally arranged and adhered on the upper surface 111 of the substrate 11. The lid 13 has a cap-shaped appearance and forms a containing compartment 14 with the upper surface 111 of the substrate 11 for containing the surface mountable components 12. The lid 13 is composed of an outer lid 15 and an inner lid 16, wherein both the outer lid 15 and the inner lid 16 are formed with conductive materials and have cap-shaped appearances. The lower ends of the outer lid 15 and the inner lid 16 are adhered to the upper surface 111 of the substrate 11 by conductive glue 17. The outer lid 15 and the inner lid 16 have pluralities of corresponding pervious holes 18 so as to communicate with outward environment. Each of the pervious holes 18 comprises a barrier 19 sandwiched between the outer lid 15 and the inner lid 16 for preventing mist, impurities, or light from entering the containing compartment 14 to impact the surface mountable components 12.

The disadvantages of the conventional semiconductor device package 1 are described as below. First, the surface mountable components 12 are horizontally arranged so that the total width of the conventional semiconductor device package 1 along the horizontal direction is enlarged. Secondly, during the manufacture process, the outer lid 15 and the inner lid 16 have to be coupled tightly before they are adhered to the upper surface 111 of the substrate 11, whose orientation is not easy, resulted in increasing the difficulty of manufacture.

Accordingly, an innovative and improved semiconductor device package structure has to be provided to solve the above-mentioned problem.

### SUMMARY OF THE INVENTION

The primary objective of the claimed invention is to provide a semiconductor device package comprising a carrier, a first semiconductor device, a second semiconductor device, a plurality of conductive elements, a pre-mold and a lid. The carrier comprises an upper surface. The first semiconductor device is electrically connected to the carrier. The second semiconductor device is disposed above the first semiconductor device. The conductive elements are used for electrically connecting the second semiconductor device and the upper surface of the carrier. The pre-mold and the upper surface of the carrier form a containing compartment for containing the first semiconductor device, the second semiconductor device, and the conductive elements, and the pre-mold has an opening. The lid is adhered to and covers the opening of the pre-mold. Accordingly, since the pre-mold is formed by molding, the manufacture process is simpler than that of the conventional semiconductor device package and the problem of difficult orientation of the conventional outer lid and inner lid is solved. Furthermore, passive devices are capable of being disposing in the pre-mold and that is an unreachable functionality for the conventional outer lid and the conventional inner lid. In addition, the second semiconductor device is disposed above the first semiconductor device so that the total width of the semiconductor device package along the horizontal direction can be decreased.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a sectional-view schematic diagram of a prior-art semiconductor device package disclosed by U.S. Pat. No. 6,781,231 B2.

FIG. 2 is a sectional-view schematic diagram of a semiconductor device package according to a first embodiment of the present invention.

FIG. 3 is a sectional-view schematic diagram of a semiconductor device package according to a second embodiment of the present invention.

FIG. 4 is a sectional-view schematic diagram of a semiconductor device package according to a third embodiment of the present invention.

FIG. 5 is a sectional-view schematic diagram of a semiconductor device package according to a fourth embodiment of the present invention.

### DETAILED DESCRIPTION

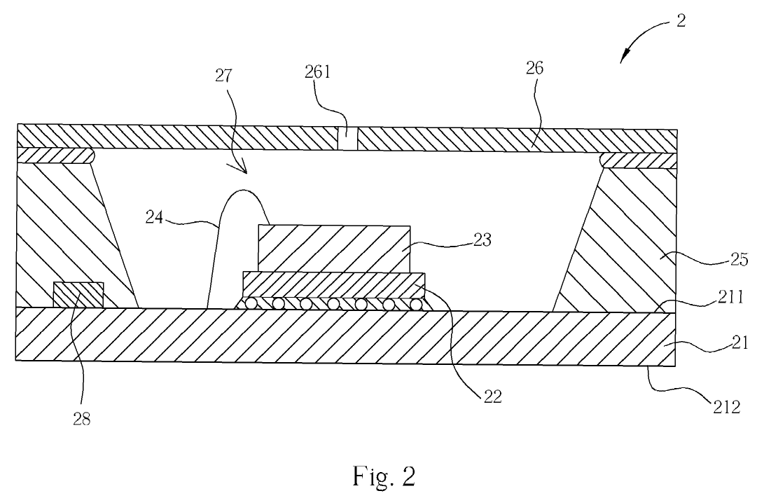

Please refer to FIG. 2, which is a sectional-view schematic diagram of a semiconductor device package according to a first embodiment of the present invention. The semiconductor device package 2 comprises a carrier 21, a first semiconductor device 22, a second semiconductor device 23, a plurality of conductive elements 24 (such as pluralities of conductive wires), a pre-mold 25 and a lid 26. The carrier 21 comprises an upper surface 211 and a lower surface 212. In this embodiment, the carrier 21 is a substrate. However, it is understandable that the carrier 21 may also be a leadframe.

The first semiconductor device 22 is electrically connected to the carrier 21. According to this embodiment, the first semiconductor device 22 is a chip and disposed on the upper surface 211 of the carrier 21 by a flip-chip way. However, it is understandable that the first semiconductor device 22 may be a package structure.

The second semiconductor device 23 is disposed above the first semiconductor device 22. In this embodiment, the area of the second semiconductor device 23 is smaller than that of the first semiconductor device 22. As a result, the second semiconductor device 23 is directly adhered to the upper surface of the first semiconductor device 22. The second semiconductor device is a MEMS device, such as a transducer, a microphone, an IC or the like. The conductive elements 24 are used for electrically connecting the second semiconductor device 23 and the upper surface 211 of the carrier 21.

The pre-mold 25 has a ring-shaped sidewall appearance and is formed by molding. The pre-mold 25 and the upper surface 211 of the carrier 21 form a containing compartment 27 for containing the first semiconductor device 22, the second semiconductor device 23 and the conductive elements 24, and the pre-mold 25 comprises an opening. The lid 26 is stuck over the pre-mold 25 and covers the opening of the pre-mold 25. The lid 26 has at least a pervious hole 261 so as to communicate with outward environment. Preferably, the semiconductor device package 2 further comprises a plurality of passive devices 28 positioned on the upper surface 211 of the carrier 21 inside the pre-mold 25.

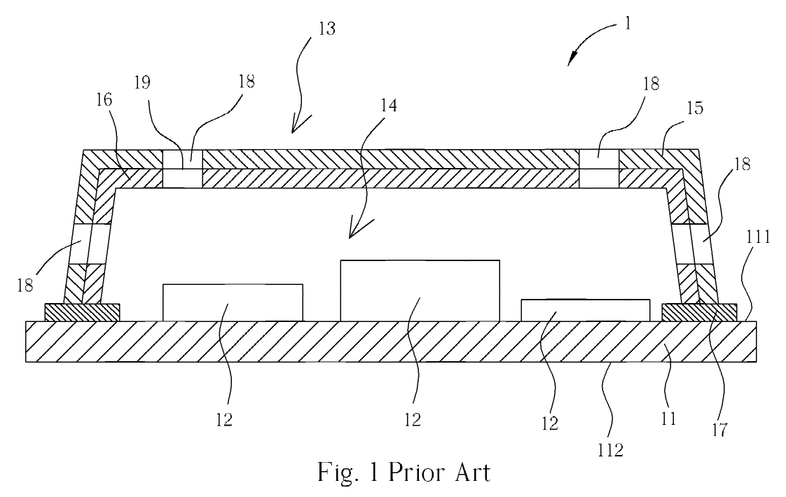

In the semiconductor device package 2, the pre-mold 25 is formed by molding, and therefore the manufacture process is simpler than that of a conventional semiconductor device package 1 (shown in FIG. 1) without the problem of difficult orientation of the conventional outer lid 15 and inner lid 16. On the other hand, it is practicable for the pre-mold 25 to comprise the passive devices 28 disposed therein, which provides a functionality that is unreachable for the conventional outer lid 15 and the inner lid 16. In addition, the second semiconductor device 23 is positioned above the first semiconductor device 22 so that the whole width of the semiconductor device package 2 along the horizontal direction is decreased.

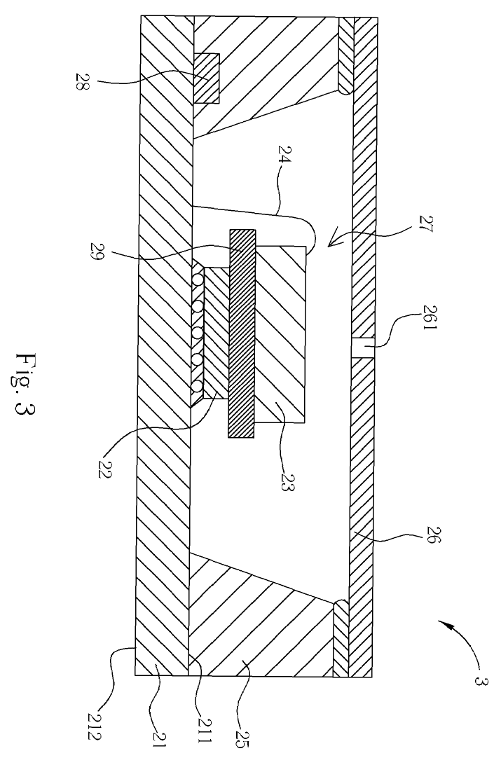

Referring to FIG. 3, FIG. 3 shows a sectional-view schematic diagram of a semiconductor device package according to a second embodiment of the present invention. The semiconductor device package 3 of this embodiment is similar to the semiconductor device package 2 of the first embodiment (shown in FIG. 2), wherein the same elements are represented with the same numerals. The only difference between the semiconductor device package 3 of the second embodiment and the semiconductor device package 2 of the first embodiment in FIG. 2 is that the area of the second semiconductor device 23 is larger than the area of the first semiconductor device 22. As a result, a spacer 29 has to be disposed between the first semiconductor device 22 and the second semiconductor device 23.

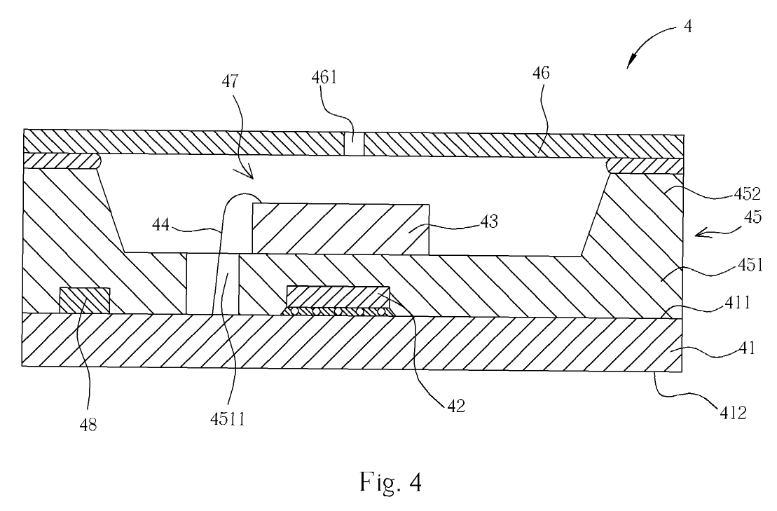

Please refer to FIG. 4, which illustrates a sectional-view schematic diagram of a semiconductor device package according to a third embodiment of the present invention. The semiconductor device package 4 comprises a carrier 41, a first semiconductor device 42, a second semiconductor device 43, a plurality of conductive elements 44, such as pluralities of conductive wires, a pre-mold 45 and a lid 46. The carrier 41 has an upper surface 411 and a lower surface 412. In this embodiment, the carrier 41 is a substrate. However, it is understandable that the carrier 41 may be a leadframe.

The first semiconductor device 42 is electrically connected to the carrier 41. According to this embodiment, the first semiconductor device 42 is a chip and disposed on the upper surface 411 of the carrier 41 by a flip-chip way. However, it is understandable that the first semiconductor device 42 may be a package structure.

The pre-mold 45 is formed by molding and comprises a bottom portion 451 and a ring sidewall portion 452. The bottom portion 451 encapsulates the first semiconductor device 42 and covers the upper surface 411 of the carrier 41, and the bottom portion 451 has a through hole 4511 exposing a portion of the upper surface 411 of the carrier 41. The bottom portion 451 and the ring sidewall portion 452 form a containing compartment 47.

The second semiconductor device 43 is disposed inside the containing compartment 47 and may be arranged at any position on the upper surface of the bottom portion 451 of the pre-mold 45. The second semiconductor device 43 is a MEMS device, such as a transducer, a microphone, an IC, or the like.

The conductive elements 44 are used for electrically connecting the second semiconductor device 43 and the upper surface 411 of the carrier 41 by pass through the through hole 4511 of the bottom portion 451. The lid 46 is adhered to the ring sidewall portion 452 of the pre-mold 45 and covers the containing compartment 47 of the pre-mold 45. The lid 46 comprises at least a pervious hole 461 so as to communicate with outward environment. Preferably, the semiconductor device package 4 further comprises a plurality of passive devices 48 positioned on the upper surface 411 of the carrier 41 inside the bottom portion 451 of the pre-mold 45.

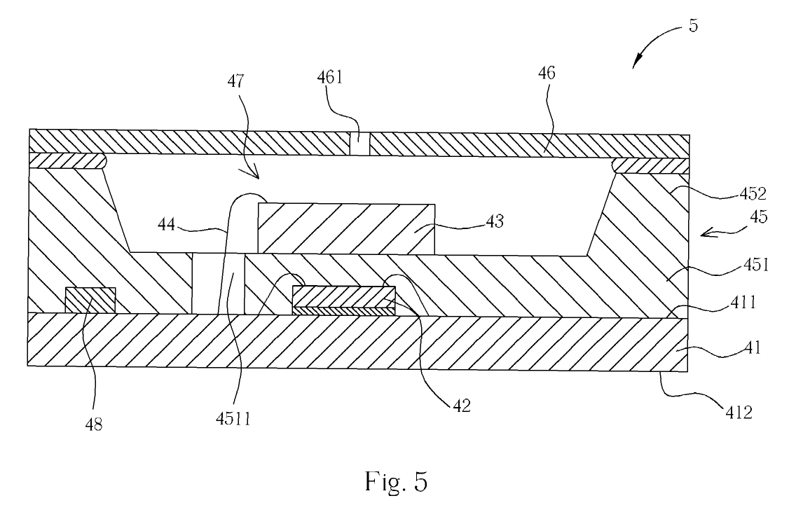

FIG. 5 is a sectional-view schematic diagram of a semiconductor device package according to a fourth embodiment of the present invention. The semiconductor device package 5 of this embodiment is similar to the semiconductor device package 4 of the third embodiment shown in FIG. 4, wherein the same elements are represented by the same numerals. The difference between the semiconductor device package 5 of this embodiment and the semiconductor device package 4 of the third embodiment shown in FIG. 4 is only that the first semiconductor device 42 of this embodiment is a chip adhered to the upper surface 411 of the carrier 41 and is electrically connected to the upper surface 411 of the carrier 41 by wiring in this embodiment.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device package comprising:
a carrier comprising an upper surface;
a first semiconductor device electrically connected to the carrier;
a second semiconductor device disposed above the first semiconductor device;
a plurality of conductive elements used for electrically connecting the second semiconductor device and the upper surface of the carrier;
a pre-mold, the upper surface of the carrier and the pre-mold forming a containing compartment for containing the first semiconductor device, the second semiconductor device and the conductive elements, and the pre-mold comprising an opening; and
a lid adhered to and covering the opening of the pre-mold.

2. The semiconductor device package of claim 1, wherein the carrier is a substrate.

3. The semiconductor device package of claim 1, wherein the carrier is a leadframe.

4. The semiconductor device package of claim 1, wherein the first semiconductor device is a chip and is attached to the upper surface of the carrier by a flip-chip way.

5. The semiconductor device package of claim 1, wherein the first semiconductor device is a package structure.

6. The semiconductor device package of claim 1, wherein the second semiconductor device is a micro-electro-mechanical system (MEMS).

7. The semiconductor device package of claim 1 further comprising a plurality of passive devices positioned on the upper surface of the carrier and inside the pre-mold.

8. The semiconductor device package of claim 1 further comprising a spacer disposed between the first semiconductor device and the second semiconductor device.

9. The semiconductor device package of claim 1, wherein the lid comprises at least a pervious hole.

10. The semiconductor device package of claim 1, wherein the conductive elements are conductive wires.

11. A semiconductor device package comprising:
a carrier comprising an upper surface;
a first semiconductor device electrically connected to the carrier;
a pre-mold comprising a bottom portion and a ring sidewall portion, the bottom portion encapsulating the first semiconductor device and covering the upper surface of the carrier, the bottom portion comprising a through hole for exposing a portion of the upper surface of the carrier, and the bottom portion and the ring sidewall portion forming a containing compartment;
a second semiconductor device disposing inside the containing compartment on the bottom portion of the pre-mold;
a plurality of conductive elements for electrically connecting the second semiconductor device and the upper surface of the carrier by passing through the through hole of the bottom portion; and
a lid adhered to and covering the containing compartment of the pre-mold.

12. The semiconductor device package of claim 11, wherein the carrier is a substrate.

13. The semiconductor device package of claim 11, wherein the carrier is a leadframe.

14. The semiconductor device package of claim 11, wherein the first semiconductor device is a chip and is attached to the carrier by a flip-chip way.

15. The semiconductor device package of claim 11, wherein the first semiconductor device is a chip that is adhered to the upper surface of the carrier and electrically connected to the upper surface of the carrier by wiring.

16. The semiconductor device package of claim 11, wherein the first semiconductor device is a package structure.

17. The semiconductor device package of claim 11, wherein the second semiconductor device is a MEMS.

18. The semiconductor device package of claim 11, further comprising a plurality of passive devices disposed on the upper surface of the carrier inside the bottom portion of the pre-mold.

19. The semiconductor device package of claim 11, wherein the lid comprises at least a pervious hole.

20. The semiconductor device package of claim 11, wherein the conductive elements are conductive wires.
